(19) United States
(12) Patent Application Publication
(10) Pub. No.: US 2025/0112138 A1
(43) Pub. Date: Apr. 3, 2025

(54) MICROELECTRONIC STRUCTURES INCLUDING GLASS SUBSTRATES WITH DIELECTRIC BASED LINER MATERIALS.

(71) Applicant: Intel Corporation, Santa Clara, CA (US)

(72) Inventors: Srinivas Pietambaram, Chandler, AZ (US); Gang Duan, Chandler, AZ (US); Sameer Paital, Mesa, AZ (US); Zhixin Xie, Chandler, AZ (US); Rahul Manepalli, Chandler, AZ (US); Jieying Kong, Chandler, AZ (US)

(73) Assignee: Intel Corporation, Santa Clara, CA (US)

(21) Appl. No.: 18/374,592

(22) Filed: Sep. 28, 2023

(51) Int. Cl. H01L 23/498; H01L 21/48; H01L 23/00; H01L 23/15

(52) U.S. Cl. CPC H01L 23/49827; H01L 21/481; H01L 21/486; H01L 23/49894; H01L 23/15; H01L 24/13; H01L 24/16; H01L 2224/13111; H01L 2224/13139; H01L 2224/13147; H01L 2224/16225

(57) ABSTRACT

Microelectronic integrated circuit package structures include an apparatus having a substrate comprising a layer of glass, the substrate comprising one or more through glass vias (TGVs) extending through the layer of glass. Individual TGVs comprise a TGV sidewall, an organic dielectric layer on the TGV sidewall and a conductive layer on the organic dielectric layer.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

Some multi-die package architectures may include IC die attached to a glass substrate and coupled to electrically conductive through-glass vias (TGVs) extending through the glass substrate. However, glass substrates possess a significantly lower coefficient of thermal expansion (CTE) than the CTEs of many conductive materials. Consequently, thermal cycling during the fabrication and operation of the TGVs may generate thermal stress in and around TGVs, which could lead to reliability issues as well as reduced device yields.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A-1E are cross-sectional views of IC package structures comprising dielectric based liner materials, in accordance with some embodiments.

FIGS. 2A-2F are cross-sectional views of IC package structures comprising dielectric based liner materials, in accordance with some embodiments.

FIGS. 3A-3D are cross-sectional views of IC package structures comprising dielectric based liner materials, in accordance with some embodiments.

FIGS. 4A-4C are cross-sectional views of IC package structures comprising dielectric based liner materials, in accordance with some embodiments.

FIGS. 5A-5D are cross-sectional views of IC package structures comprising dielectric based liner materials, in accordance with some embodiments.

FIGS. 6A-6C are cross-sectional views of IC package structures comprising dielectric based liner materials, in accordance with some embodiments.

FIG. 7 is a cross-sectional view of an IC package structure comprising dielectric based liner materials, in accordance with some embodiments.

FIGS. 8A-8B illustrate flow charts of processes for the fabrication of IC package structures having dielectric based liner materials, in accordance with some embodiments.

FIG. 9 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dies and leads, pins or bumps located on the external portions of the package substrate. The package may contain a single die, or multiple dies, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods employing glass substrates. Such methods include the use of through glass vias (TGVs) to produce high input/output (I/O) density devices with minimal warpage. Glass substrates can be formed with tunable CTEs, smaller total thickness variation (TTV) and tunable optical properties. Glass based substrates or interposers can provide better interconnect performance in advanced 2.5D and 3D packaging structures. Copper filled TGVs provide vertical electrical connections and facilitate heat dissipation in advanced packaging structures.

However, due to the CTE mismatch between conductive materials and glass, thermal cycling during the fabrication and operation of the TGVs can generate thermal stress in and around the TGVs. To release thermal stress, an organic dielectric liner or buffer layer can be introduced between the conductive material in the TGV and the glass. Decoupling the conductive material from the glass sidewalls through the use of low modulus liners can recover the glass strength back to its original levels. Such low modulus liners can include metallic liners, Parylene liners or combinations of metallic and organic dielectric liners.

Embodiments describe a substrate comprising a layer of glass, the substrate comprising one or more TGVs extending through the layer of glass. The glass substrate may comprise an interposer or a core. The one or more TGVs comprise a TGV sidewall. An organic dielectric layer may be formed on the TGV sidewall, where in an embodiment the organic dielectric material may be molded into the TGVs of the glass substrate. A wide range of organic dielectric materials can be selected with suitable CTE and modulus values to buffer stress occurring during thermal cycling, for example, of a conductive material plated to fill the TGVs. Subsequent to the molding process, the organic dielectric material may be plugged into the TGVs.

The organic dielectric mold material within the TGVs may then be drilled by utilizing a mechanical drilling, a laser drilling, or an ultra violet (UV) lithographic process to form openings in the organic dielectric material. In an embodiment, a conductive layer may be formed on the organic dielectric layer by utilizing a plating process, for example. In an embodiment, the conductive material may fill the opening in the organic dielectric material. An essential component that enables the glass interposer or core is a conductive material filled TGV which provides vertical electrical connections and facilitates heat dissipation. The conductive material provides an interconnect path with which to conductively couple the glass substrate to devices within a package structure. An electrical routing structure comprising redistribution layer (RDL) metallization may be built-up on at least one side of the glass substrate, and IC die(s) may be assembled to the routing structure. method to improve TGV reliability with dielectric based liner materials.

The embodiments herein enable a cost-efficient process that can prevents TGV failure. Molding equipment used according to embodiments herein facilitate the plug of organic dielectrics into the TGVs.

The architecture described herein may be assembled and/or fabricated with one or more of the features or attributes provided in accordance with various embodiments. A number of different assembly and/or fabrication methods may be practiced to TGVs with organic dielectric liners within a glass package structure, according to one or more of the features or attributes described herein.

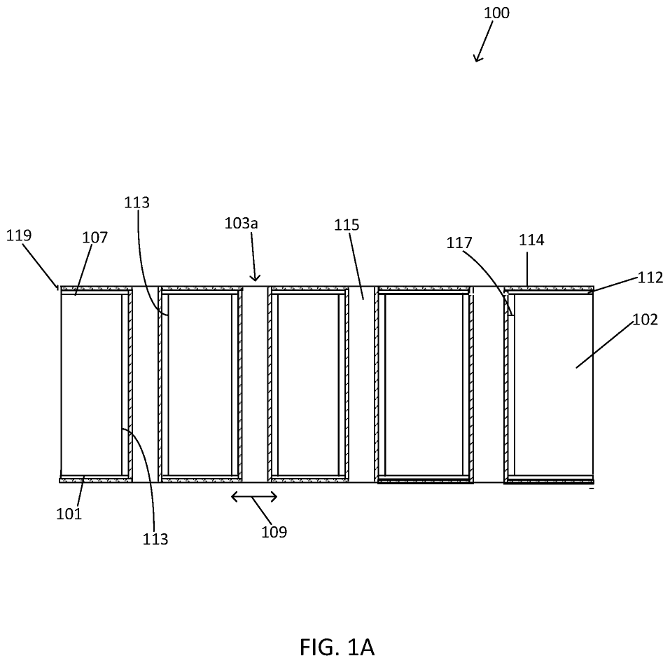

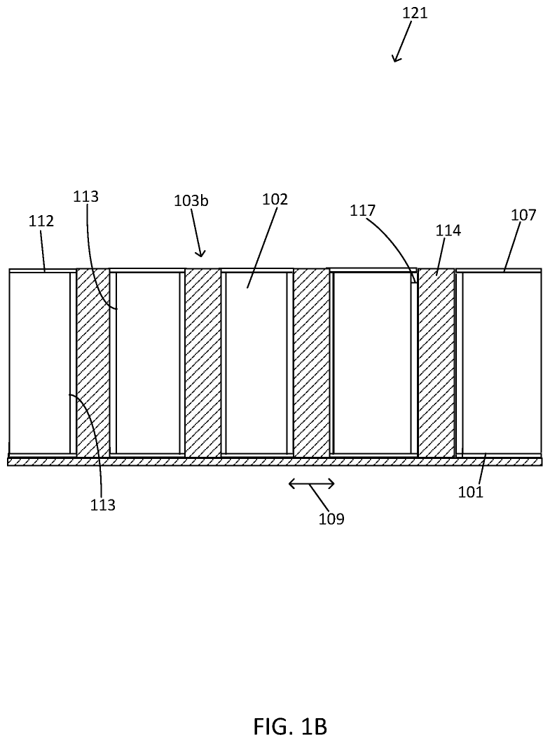

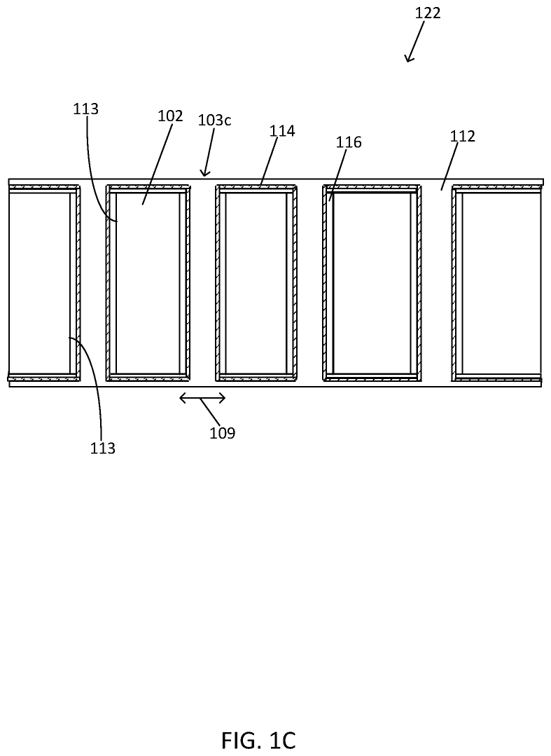

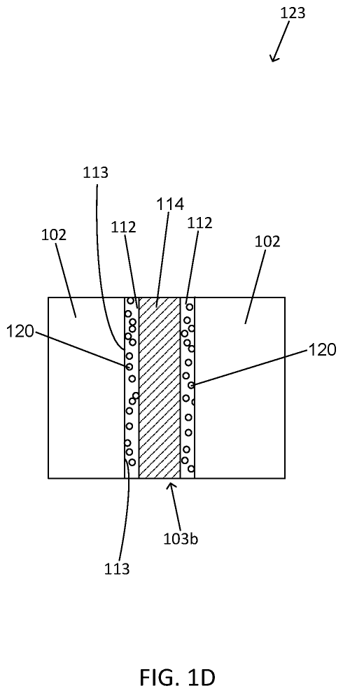

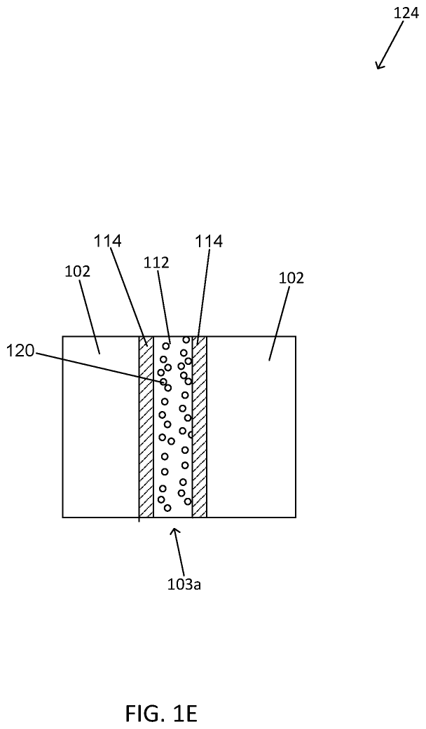

FIGS. 1A-1E illustrate embodiments of package structures including to TGVs with organic dielectric liners. The package structures are formed utilizing standard deposition and lithographic processing techniques. The methods of fabrication described herein create improved interconnect performance in advanced 2.5D and 3D packaging.

FIG. 1A is a cross-sectional view of a portion of integrated circuit (IC) package structure 100, in accordance with some embodiments. As shown, a substrate 102 comprises a glass layer 102, wherein the glass layer 102 comprises one or more of aluminosilicate, borosilicate, alumino-borosilicate, silica, or fused silica. The glass layer 102 may include one or more additives, such as Al2O3, B2O3, MgO, CaO, SrO, BaO, SnO2, Na2O, K2O, SrO, P2O3, ZrO2, Li2O, Ti, or Zn. In an embodiment, the glass may comprise silicon and oxygen, as well as any one or more of aluminum, boron, magnesium, calcium, barium, tin, sodium, potassium, strontium, phosphorus, zirconium, lithium, titanium, and zinc.

In an embodiment, the glass layer 102 may comprise at least 23 percent silicon and at least 26 percent oxygen by weight, and further may comprise at least 5 percent aluminum by weight. In an embodiment the glass layer 102 may comprise a solid layer of glass rectangular in shape in plan view. In an embodiment, the layer of glass 102 does not include an organic adhesive or an organic material. The substrate 102 may comprise a glass core or a glass interposer which provides mechanical benefit such as reduced warpage, smaller thickness variation and design flexibility by providing tighter through hole pitch and finer core routing.

An organic dielectric layer 112 may be on sidewalls 113 and on first and second surfaces 101, 107 of the substrate 102. The organic dielectric material 112 may comprise such organic materials as epoxy mold compounds, build-up dielectric (ABF), or photo-imageable dielectric (PID) materials such as polyimide materials. The organic dielectric material 112 may have micro or nano sized particulate fillers, or a mixture of fibers and particulate fillers, therein in an embodiment. The fillers in the organic dielectric material 112 may include silicates, quartz, mica, silicate, titanium dioxide, amorphous silicas, magnesium carbonate, aluminum nitride, alumina, boron nitride, magnesium hydroxide, chalk, limestone, feldspar, barium sulfate, solid or hollow fillers, permanently magnetic metal compounds, and/or alloys or mixtures thereof.

A wide range of organic dielectric materials can be selected with suitable coefficients of thermal expansion (CTE) and modulus to buffer the stress of a conductive material 114 within TGVs 103a, during thermal cycling of a package structure. For example, where the substrate comprises a CTE of 4-9 ppm/K, a CTE of the organic dielectric material 112 may be less than about 25 ppm/K. In an embodiment, the organic dielectric materials 112 may comprise an elastic modulus of less than about 15 GPa. In an embodiment, a thickness 117 of the organic dielectric layer 112 on the sidewalls 113 of the substrate 102 may comprise below about 25% of a lateral width 109 of the TGVs 103a, in an embodiment.

A conductive layer 114 may be on the organic dielectric material 112. In an embodiment, a thickness 119 of the conductive layer 114 on the organic dielectric layer 112 may comprise below about 25% of the lateral width 109 of the TGV 103a. The conductive layer 114 may comprise a copper material or copper alloys, in an embodiment, but may comprise any suitable conductive material. The conductive layer 114 forms an interconnect path with which to conductively couple any devices coupled within or to the package structure 100.

An additional organic dielectric material 115 may be within the TGVs 103a, wherein the TGVs 103a comprise the organic dielectric material 112 on the substrate 102 sidewall 113, the conductive material 114 on the organic dielectric material 112, and the additional organic dielectric material 115 on the conductive material 114. In an embodiment, the TGVs 103a comprise an organic dielectric material filled via structure 103a. In an embodiment, the additional organic dielectric material 115 may comprise a different material than the organic dielectric material 112. In other embodiments, the additional organic dielectric material 115 may comprise the same material as the organic dielectric material 112. The additional organic dielectric material 115 may comprise an organic dielectric plug for the TGVs 103a. In an embodiment, the organic dielectric layer 112 comprises a first organic dielectric layer, and the additional organic dielectric layer 115 comprises a second dielectric layer, wherein the second organic dielectric layer is on the conductive layer opposite the first organic dielectric layer.

FIG. 1B is a cross-sectional view of a portion of integrated circuit (IC) package structure 121, in accordance with some embodiments. As shown, a substrate 102 comprises a glass layer, wherein the glass layer comprises aluminosilicate, borosilicate, alumino-borosilicate, silica, and fused silica. The glass layer may include one or more additives, such as Al2O3, B2O3, MgO, CaO, SrO, BaO, SnO2, Na2O, K2O, SrO, P2O3, ZrO2, Li2O, Ti, and Zn. The glass layer may comprise silicon and oxygen, as well as any one or more of aluminum, boron, magnesium, calcium, barium, tin, sodium, potassium, strontium, phosphorus, zirconium, lithium, titanium, and zinc, and may comprise at least 23 percent silicon and at least 26 percent oxygen by weight.

An organic dielectric layer 112 may be on sidewalls 113 and on first and second surfaces 101, 107 of the substrate 102. The organic dielectric material 112 may comprise such organic materials as epoxy mold compounds, build-up dielectric (ABF), photo-imageable dielectric (PID) such as polyimide. The organic dielectric material 112 may have micro or nano sized particulate fillers, or a mixture of fibers and particulate fillers, therein in an embodiment. The fillers in the material may include silicates, quartz, mica, silicate, titanium dioxide, amorphous silicas, magnesium carbonate, aluminum nitride, alumina, boron nitride, magnesium hydroxide, chalk, limestone, feldspar, barium sulfate, solid or hollow fillers, permanently magnetic metal compounds, and/or alloys or mixtures thereof.

In an embodiment, a thickness 117 of the organic dielectric layer 112 on the sidewalls 113 of the substrate 102 may comprise below about 25% of the lateral width 109 of the TGV 103 opening, in an embodiment. A conductive material 114 may be on the organic dielectric material 112. In an embodiment, the conductive material 114 may fill one or more TGVs 103b, wherein the one or more TGVs may comprise the organic dielectric material 112 on sidewalls 113 of the substrate 102, and the conductive material on the organic dielectric material 112. A thickness 119 of the conductive layer 114 on the organic dielectric layer 112 may comprise above about 30% of the lateral width 109 of the TGVs/via structure 103b.

The conductive material 114 may comprise a copper material or copper alloys, in an embodiment, but may comprise any suitable conductive material. The conductive material 114 forms an interconnect path with which to conductively couple any devices coupled within or to the package structure 100, wherein the conductive material 114 comprises a conductive TGV 103b plug. In an embodiment, the conductive material 114 may be on a surface 101 of the substrate 102, wherein individual TGVs 103b are conductively coupled to each other.

FIG. 1C is a cross-sectional view of a portion of integrated circuit (IC) package structure 122, in accordance with some embodiments. As shown, a substrate 102 comprises a glass layer, similar to the glass layer 102 of FIG. 1A for example. The substrate 102 may comprise a glass core or an interposer in an embodiment, and may provide mechanical benefits such as reduced warpage, smaller thickness variation and design flexibility (tighter through hole pitch, finer core routing).

A thin layer 116 may be on sidewalls 113 and on first and second surfaces 101, 107 of the substrate 102. The thin layer 116 may comprise a parylene material or a conductive material such as aluminum. In an embodiment, the thin layer 116 may comprise a thickness of less than 25 percent of the lateral width of the one or more TGVs 103c. A conductive material 114 may be on the thin layer 116. The conductive material 114 may comprise any suitable conductive material, such as copper or copper alloys, for example. In an embodiment, an organic dielectric material 112 may be on the conductive material 114.

The organic dielectric material 112 may comprise such organic dielectric materials as epoxy mold compounds, build-up dielectric (ABF), photo-imageable dielectric (PID) such as polyimide. The organic dielectric material 112 may have micro or nano sized particulate fillers, or a mixture of fibers and particulate fillers, therein in an embodiment. The fillers in the material may include silicates, quartz, mica, silicate, titanium dioxide, amorphous silicas, magnesium carbonate, aluminum nitride, alumina, boron nitride, magnesium hydroxide, chalk, limestone, feldspar, barium sulfate, solid or hollow fillers, permanently magnetic metal compounds, and/or alloys or mixtures thereof.

A CTE of the organic dielectric material 112 may be less than about 25 ppm/K. In an embodiment, the organic dielectric materials may comprise an elastic modulus of less than about 15 GPa. In an embodiment, a thickness of the organic dielectric layer 112 on the conductive layer 114 may comprise above about 25% of the lateral width 109 of the one or more TGVs 103c, in an embodiment, wherein the organic dielectric layer may be a plug of the TGVs 103c. In embodiment, the one or more TGVs 103c may comprise the thin layer 116 on sidewalls 113 of the substrate 102, the conductive layer 114 on the thin layer 116 and the organic dielectric material 112 on the thin layer 116.

FIGS. 1D-1E depict portions of the glass substrate 102 of package structures 123, 124 wherein the organic dielectric material 112 in the via structures 103b comprise a plurality of hollow filler material. In FIG. 1D, the organic dielectric material 112 of the portion of integrated circuit (IC) package structure 122 comprises the hollow filler material 120. The organic dielectric material 112 is on the sidewalls 113 of the glass substrate 102. In an embodiment, a concentration of the hollow filler material 120 within the organic dielectric material 112 comprises about 1-85% weight percentage. A conductive material 114 fills the via 103b. In FIG. 1E, the portion of integrated circuit (IC) package structure 124 is depicted wherein a conductive material 114 is on the sidewalls 113 of the glass substrate 102. The organic dielectric material 112 comprising the hollow filler material 120 fills the via 103a.

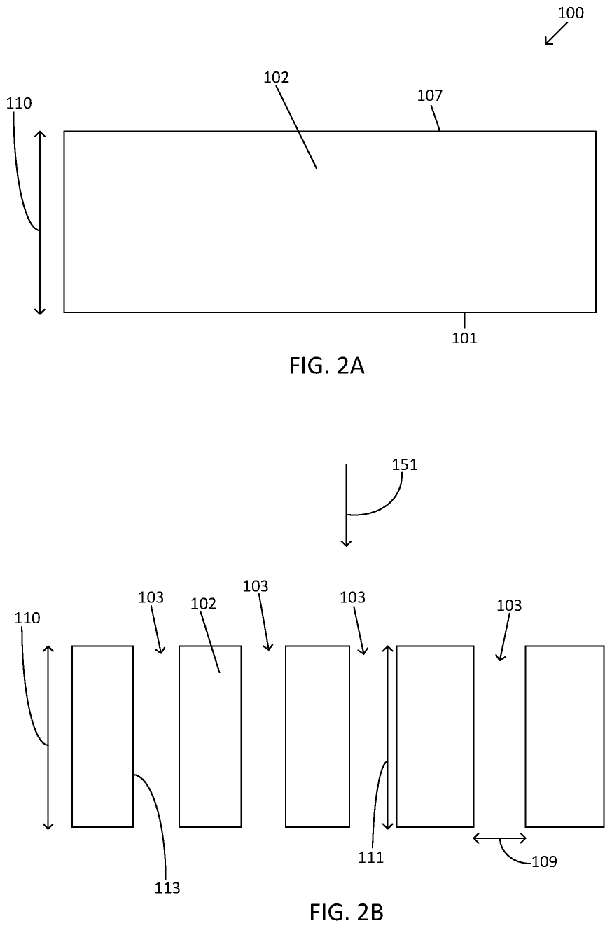

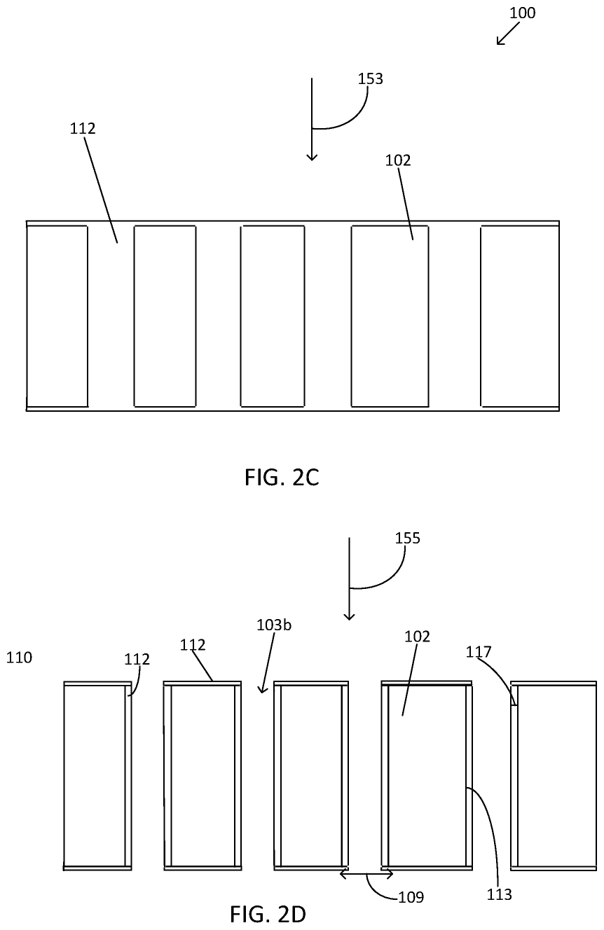

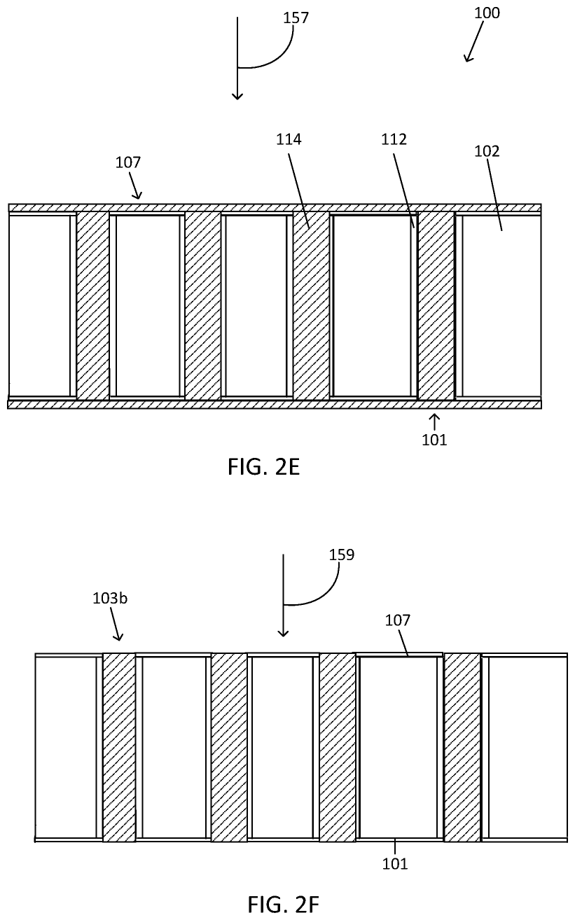

FIGS. 2A-2F illustrate embodiments of forming IC package structures (such as the IC package structures of (FIGS. 1A-1E). FIG. 2A depicts a cross-sectional view of a portion of substrate 102 according to some embodiments. As shown, the substrate 102 may comprise a glass layer 102. IC device package structures may be fabricated upon substrate 102. Substrate 102 comprises as flatness and/or thickness control for a preform of glass which is superior to that of starting substrates based on organic materials (e.g., epoxy), and costs can be significantly lower than for monocrystalline materials (e.g., silicon). Substrate 102 may comprise a solid bulk material layer that may have been previously formed into any shape in plan view (e.g., x-y plane) suitable for a packaging workpiece, such as rectangular shape.

Substrate 102 comprises a thickness 110 which may be optimized according to particular design requirements, for example to limit warpage while remaining thin enough to permit the formation of through glass vias (TGVs) at a pitch which is optimized for particular design requirements. In exemplary embodiments, the thickness 110 may comprise between about 200 microns to about 2000 microns.

Substrate 102 is advantageously predominantly silicon and oxygen. In some embodiments, substrate 102 comprises at least 23 percent silicon and at least 26 percent oxygen, by weight (i.e., wt. %). Substrate 102 may further include one or more additives, such as, aluminum, boron, magnesium, calcium, barium, tin, sodium, potassium, strontium, phosphorus, zirconium, lithium, titanium, or zinc. In some embodiments where substrate 102 comprises at least 23 wt. % Si and at least 26 wt. % O, substrate 102 further comprises at least 5 wt. % Al. Additives within substrate 102 may form suboxides (A2O) monoxides (AO), binary oxides (AO2), ternary oxides (ABO3), and mixtures thereof. For example, substrate 102 may comprise AlOx (e.g., Al2O3), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx (e.g., P2O3), ZrOx (e.g., ZrO2), LiOx (e.g., Li2O), TiOx (e.g., TiO2), or ZnOx (e.g., ZnO2). Depending on chemical composition, substrate 102 may therefore be referred to as silica, fused silica, aluminosilicate, borosilicate, or alumino-borosilicate, for example.

Substrate 102 is advantageously a bulk material of substantially homogeneous composition in contrast to a composite material that may merely comprise glass fillers and/or fibers. Although substrate 102 is substantially amorphous in some embodiments, substrate 102 may also have other morphology or microstructure, such as polycrystalline (e.g., nanocrystalline).

Although not depicted, one or more material layers may clad on either or both of a first surface 101 or a second surface 107, wherein the first surface 101 is opposite the second surface 107, so that in an embodiment substrate 102 may comprise a bulk or core layer of a multi-layered substrate 102. Exemplary cladding materials include inorganic materials such as silicon nitride (SiNx) or silicon oxynitride (SiOxNy). In other embodiments, a silicon layer (polycrystalline or monocrystalline) may clad first and/or second surfaces 101, 107 of substrate 102. Organic material layers, such as polymer dielectric materials, may also clad first and/or second surfaces 101, 107 of substrate 102.

In FIG. 2B, a process 151 may be employed to form one or more TGVs 103a within and through the substrate 102. Process 151 may comprise such processes as a drilling or chemical etch processes. In an embodiment, any process known to be suitable for forming TGVs 103a in bulk glass may be utilized. In some embodiments, a laser ablation process, a glass etch process (laser-assisted, or otherwise), or any other such techniques known to be suitable for forming features (e.g., holes) through a thickness of the substrate may be employed to achieve a desired diameter and feature pitch of the one or more TGVs 103a.

In an embodiment, a length 111 of sidewalls 113 of individual TGVs 103a may comprise substantially the same magnitude as the thickness 110 of the substrate 102. In other words, the one or more TGVs 103a extend through the thickness 110 of the substrate 102. In an embodiment, a width 109 of the one or more TGVs 103a may comprise between about 50 microns and 100 microns but may be optimized depending upon the particular application.

A process 153 may be employed wherein an organic dielectric material 112 may be formed on the substrate 102 and at least partially within the one or more TGVs 103 (FIG. 2C). In an embodiment, the process 153 may comprise such processes as chemical vapor deposition (CVD), physical vapor deposition (PVD), slit coating, lamination or molding methods. Molding processes may include but are not limited to compression molding, lamination, hot pressing or transfer molding.

The organic dielectric material 112 may comprise such organic materials as epoxy mold compounds, build-up dielectric (ABF), photo-imageable dielectric (PID) such as polyimide. The organic dielectric material 112 may have micro or nano sized particulate fillers, or a mixture of fibers and particulate fillers, therein in an embodiment. The fillers in the material may include silicates, quartz, mica, silicate, titanium dioxide, amorphous silicas, magnesium carbonate, aluminum nitride, alumina, boron nitride, magnesium hydroxide, chalk, limestone, feldspar, barium sulfate, solid or hollow fillers, permanently magnetic metal compounds, and/or alloys or mixtures thereof.

A wide range of organic dielectric materials 112 can be selected with suitable coefficients of thermal expansion (CTE) and modulus to buffer the stress of a conductive material subsequently formed within the TGVs 103, during thermal cycling of a package structure. For example, where the substrate 102 comprises a CTE of 4-9 ppm/K, a CTE of the organic dielectric material 112 may be less than about 25 ppm/K. In an embodiment, the organic dielectric materials 112 may comprise an elastic modulus of less than about 15 GPa.

A process 155 may be employed subsequent to the formation of the organic dielectric material 112 on the substrate 102 wherein the organic dielectric material 112 may be plugged into the one or more substrate 102 TGVs 103 (FIG. 2D). The organic dielectric material 112 may be drilled by mechanical drilling, or laser drilling, or may undergo ultraviolet (UV) lithography to form an organic dielectric layer 112 on sidewalls of the TGVs 103a. In this manner, the one or more TGVs 103b comprising the organic dielectric layer 12 on the sidewalls of the TGVs 103b comprise polymer vias 103b in glass vias (via in via structures) that enhance the mechanical strength of the glass substrate 102 and prevent crack propagation within the substrate 102. In an embodiment, a thickness 117 of the organic dielectric layer 112 on the sidewalls 113 of the TGVs 103b may comprise below about 25% of the lateral width 109 of the TGVs 103b sidewall 113 opening, in an embodiment.

A conductive material 114 may be formed on the organic dielectric layer 112, by using a formation process 157 (FIG. 2E). In an embodiment, the conductive material 114 may be formed by initially forming a conductive seed layer on the organic dielectric layer 112, and then plating the conductive material 114 on the conductive seed layer, such that the vias 103 are filled with the conductive material 114. The conductive material 114 may comprise a copper material 114 or copper alloys, in an embodiment, but may comprise any suitable conductive material. The conductive material forms an interconnect path with which to conductively couple any devices coupled within or to the package structure 100. The conductive material 114 comprises a conductive TGV 103b plug. In an embodiment, the first and/or second surfaces 101, 107 of the substrate 102 may be grinded or polished 159 to form flat, planarized surfaces 101, 107. (FIG. 2F).

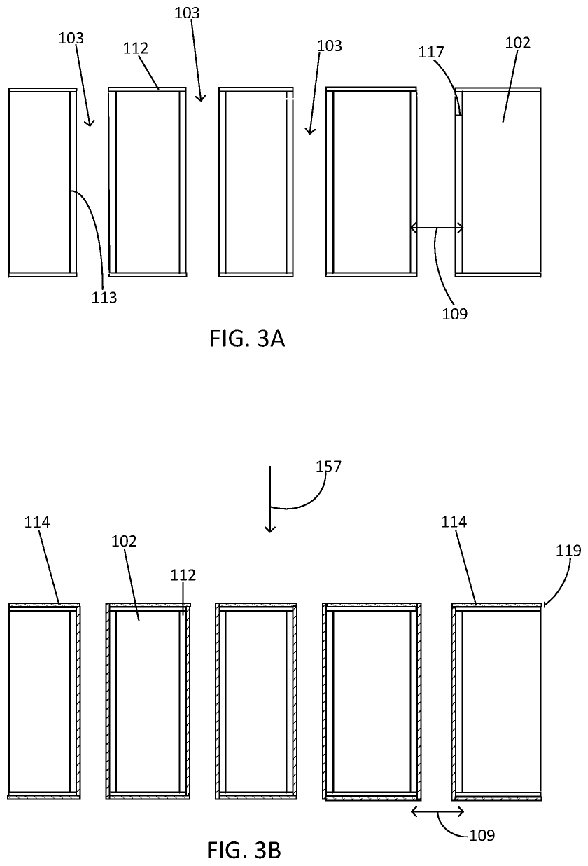

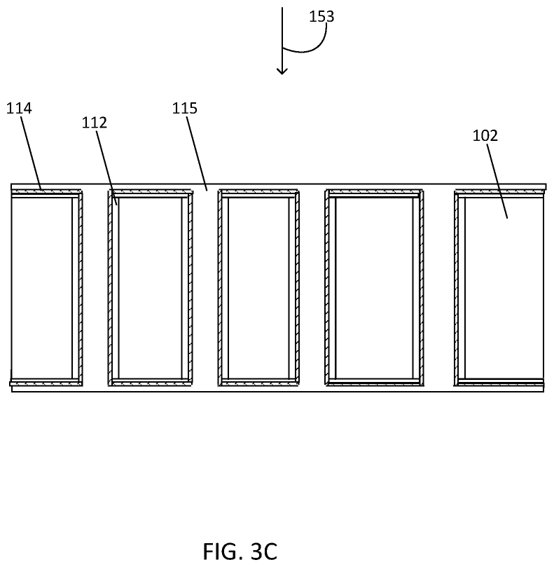

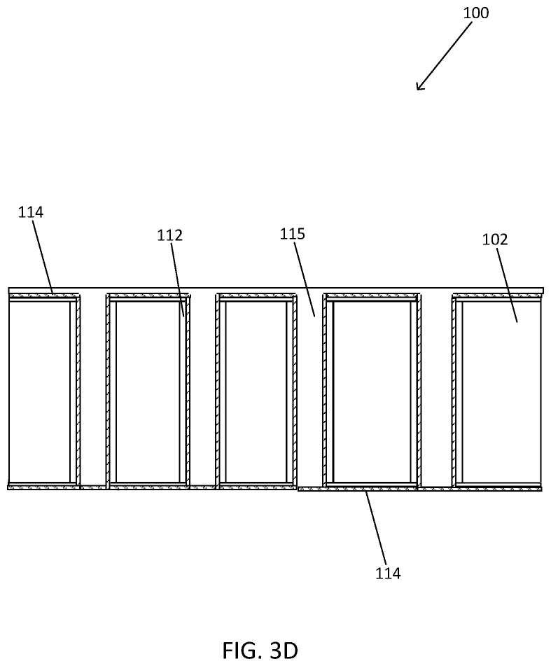

FIGS. 3A-3D depict the formation of package structures according to embodiments of the present disclosure. FIG. 3A depicts a substrate 102, similar to the substrate 102 of FIGS. 2A-2E, for example. The substrate 102 may comprise a glass layer 102. IC device package structures/devices may be fabricated upon substrate 102. One or more TGVs 103 are within and through the substrate 102. An organic dielectric layer 112, similar to the organic dielectric layer 112 of FIGS. 2A-2F, may be on sidewalls 113 of the TGVs 103a. In an embodiment, a thickness 117 of the organic dielectric layer 112 on the sidewalls 113 of the TGVs 103a may comprise below about 25% of the lateral width 109 of the TGV 103 sidewall 113 opening, in an embodiment.

In FIG. 3B, a conductive layer 114 may be formed on the organic dielectric layer 112 utilizing formation process 157, similar to the formation process of FIG. 2E, for example. In an embodiment, a thickness 119 of the conductive layer 114 on the organic dielectric layer 112 may be formed to comprise below about 25% of the lateral width 109 of the TGV 103 opening, in an embodiment. In another embodiment, the conductive material 114 may be formed to initially fill the TGV 103, and then may be drilled leaving a center of the via 103 open.

In FIG. 3C, an additional organic dielectric layer 115 may be formed on the conductive layer 114 utilizing formation process 153, similar to the formation process of FIG. 2C, for example. In an embodiment, the additional organic dielectric material 115 may comprise the same material as the organic dielectric material 112 or may comprise a different organic dielectric material. In an embodiment, the organic dielectric layer 115 material may comprise such organic materials as epoxy mold compounds, build-up dielectric (ABF), or photo-imageable dielectric (PID) such as polyimide, for example.

The additional organic dielectric material 115 may have micro or nano sized particulate fillers, or a mixture of fibers and particulate fillers, therein in an embodiment. The fillers in the material may include silicates, quartz, mica, silicate, titanium dioxide, amorphous silicas, magnesium carbonate, aluminum nitride, alumina, boron nitride, magnesium hydroxide, chalk, limestone, feldspar, barium sulfate, solid or hollow fillers, permanently magnetic metal compounds, and/or alloys or mixtures thereof.

The additional organic dielectric material 115 can be selected with suitable coefficients of thermal expansion (CTE) and modulus to buffer the stress of a conductive material subsequently formed within the TGVs 103, during thermal cycling of a package structure. For example, where the substrate comprises a CTE of 4-9 ppm/K, a CTE of the organic dielectric material may be less than about 25 ppm/K. In an embodiment, the additional organic dielectric material 115 may comprise an elastic modulus of less than about 15 GPa. In this manner, a glass-organic dielectric-conductive layer-organic dielectric via structure is formed to improve the reliability of the entire substrate 102. FIG. 3D depicts another embodiment wherein the conductive material 114 of the package structure 100 may be formed on a surface of the substrate 102, wherein the individual TGVs are electrically coupled to one another through the surface conductive layer 114.

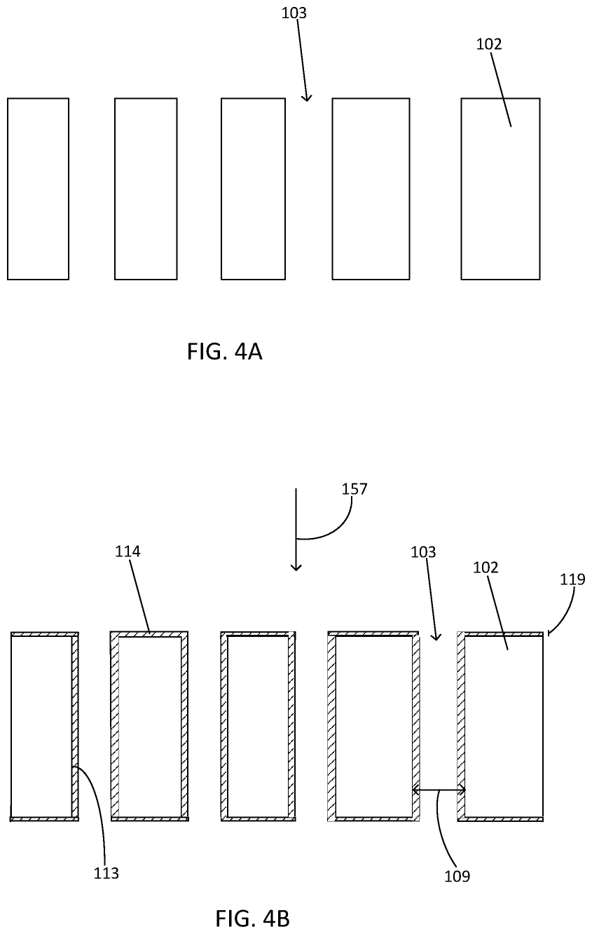

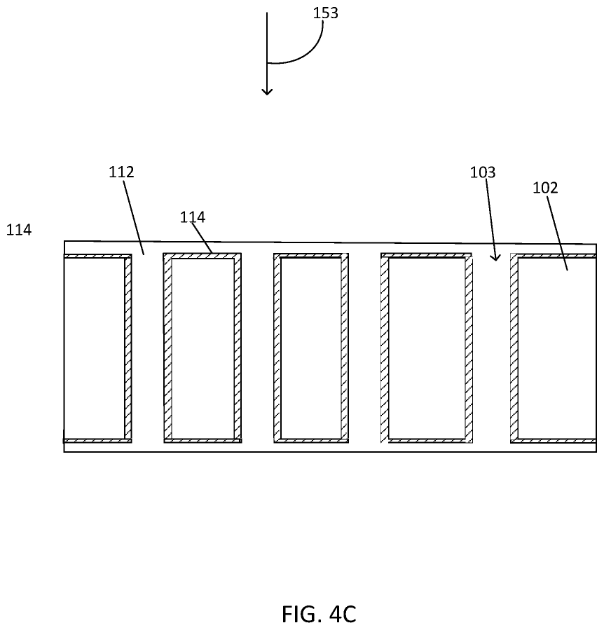

FIGS. 4A-4C depict the formation of package structures according to embodiments of the present disclosure. In FIG. 4A, a glass substrate 102 is provided wherein one or more TGVs 103 extend through the glass substrate 102. A conductive layer 114 may be formed directly on the TGV 103 sidewalls 113 utilizing a formation process 157 (FIG. 4B). The conductive layer 114 may comprise a thickness 119 that may be formed to comprise below about 25% of the lateral width 109 of the TGV 103 opening, in an embodiment. In another embodiment, the conductive material 114 may be formed to initially fill the TGV 103b, and then may be drilled leaving a center of the via 103c open.

A formation process 153 may then be employed wherein an organic dielectric material 112 may be formed on the conductive layer 114 utilizing formation process 153, similar to the formation process of FIG. 2C, for example (FIG. 4C). In an embodiment, the organic dielectric material 112 material may comprise such organic materials as epoxy mold compounds, build-up dielectric (ABF), or photo-imageable dielectric (PID) such as polyimide, for example.

A molding process may be performed to plug the organic dielectric material 112 into the center of the TGVs 103. The organic dielectric plug of the TGVs exhibit good adhesion to the conductive material 114, possesses a low modulus which can reduce the thermal contraction of the conductive material 114, and provides for thermal stress reduction while preventing delamination of the conductive material from the glass substrate 102.

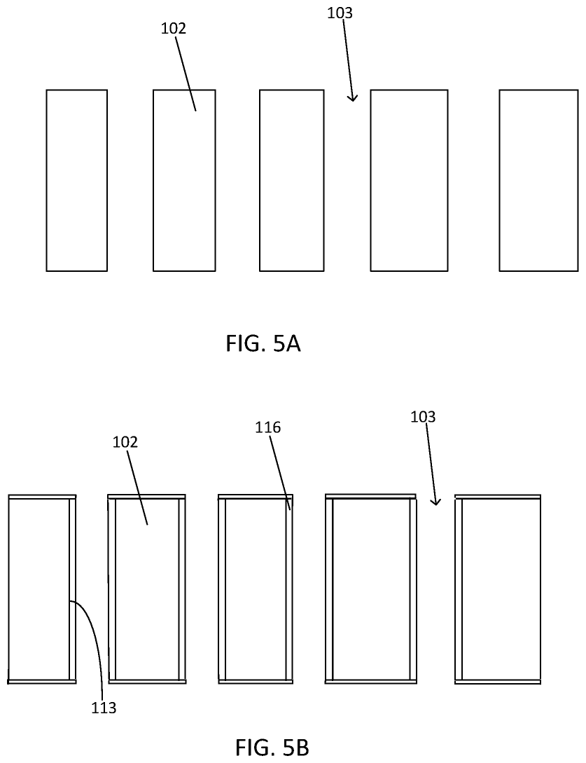

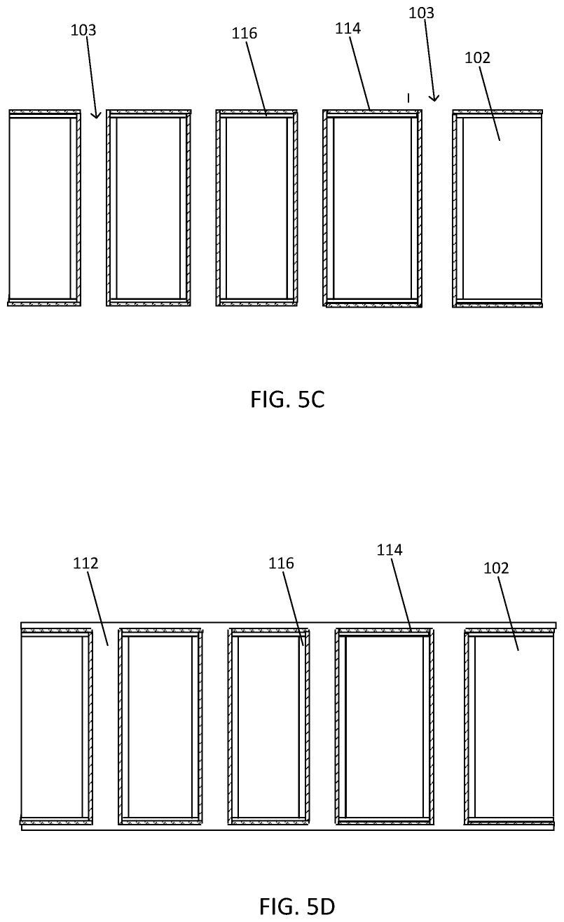

FIGS. 5A-5D depict the formation of package structures according to embodiments of the present disclosure. In FIG. 5A, a glass substrate 102 is provided wherein one or more TGVs 103 extend through the glass substrate 102. A thin layer 116 may be formed on the sidewalls 113 of the TGVs 103 (FIG. 5B). In an embodiment, the thin layer 116 may comprise a Parylene material or a thin conductive material, such as aluminum. The thin layer 116 may be formed utilizing any suitable formation process such as a physical vapor deposition process, for example, wherein the thin layer 116 may act as a stress buffer layer. A conductive layer 114 may be formed directly on the thin layer 116 (FIG. 5C). The conductive layer 114 may comprise a thickness that may be formed to comprise below about 25% of the lateral width of the TGV 103 opening, in an embodiment, leaving the TGVs 103 open. An organic dielectric material 112 is then plugged into the TGVs 103 by utilizing a molding process, for example (FIG. 5D).

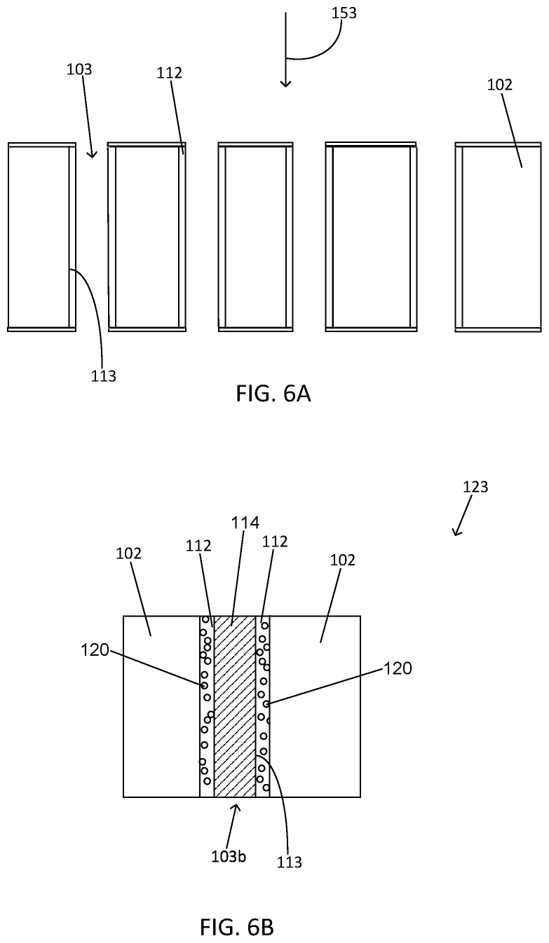

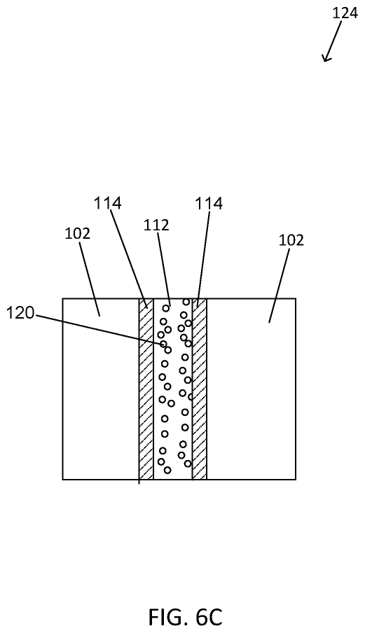

FIGS. 6A-6C depict the formation of package structures according to embodiments of the present disclosure. In FIG. 6A, a glass substrate 102 is provided wherein one or more TGVs 103 extend through the glass substrate 102. In an embodiment, a laser induced direct etching (LIDE) technique is used to sensitize etch the glass substrate 102 according to desired dimensions of the TGV structure. The glass substrate 102 is then preferentially etched at the laser sensitized zone using hydrofluoric acid to form the TGV opening structure.

An organic dielectric layer 112, similar to the organic dielectric layer 112 of FIGS. 2A-2F, may be formed 153 on sidewalls 113 of the TGVs 103. In an embodiment, the organic dielectric material 112 may comprise a plurality of hollow fillers. In an embodiment, the organic dielectric material 112 may be formed inside the TGVs 103 using a slit coating process or a lamination process or molding methods. The organic dielectric material 112 may comprise a plurality of hollow SiO2 fillers 120 in a resin material such as ABF, in an embodiment. In an embodiment the hollow fillers 120 may be filled with the ambient gas. In an embodiment, a thickness of the organic dielectric layer 112 on the sidewalls 113 of the substrate 102 may comprise below about 25% of the lateral width of the TGV 103 opening. The filled vias 103 are then drilled and metallized with a conductive material, such as copper or copper alloys to form high speed interconnects vias in package structure 123 (FIG. 6B). In an embodiment, the surface metal and organic dielectric material 112 may be planarized and metallized to form the conductive traces and pads on the substrate 102.

Instead of the hollow filler containing organic dielectric implemented as a liner, it can also be integrated into the core TGVs as a plug material. In an embodiment, a conductive layer 114 may be formed on the sidewalls of the substrate 102, followed by a via drill at a center portion of the TGV 103 and then plugged with the hollow filler containing organic dielectric material 112 using molding or slit coating or lamination process to produce package structure 124 (FIG. 6C).

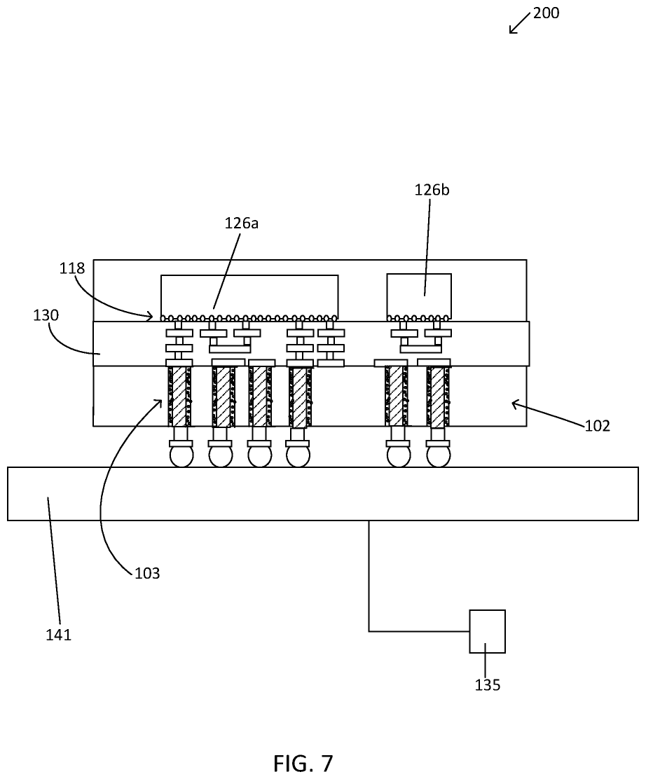

FIG. 7 depicts an IC package structure 200, wherein dies 126a, 126b are on a substrate 102, such as a package substrate 102 of FIG. 1A, for example. In some embodiments, the dies 126a, 126b may comprise chiplet structures 126a, 126b which may comprise components of a system on a chip (SOC) structure. The dice 126a, 126b are coupled to each other and to a glass substrate 102 (such as the glass substrate of FIG. 2A-2F, for example), including TGV vias 103, according to any of the embodiments disclosed herein, through a redistribution layer (RDL) metallization 130. Any number of die/devices may be couple to the substrate 102. The substrate 102 may be coupled to a board 141, such as a printed circuit board, in an embodiment. Conductive bumps 118 may comprise any conductive element for coupling to an outside die or other device. In an embodiment, the conductive bumps 118 may include silver, tin, or copper, or combinations or alloys thereof. A power supply 135, which may comprise any suitable power supply as known in the art, may be coupled to dies 126a, 126b via IC package structure 200, in an embodiment.

Discussion now turns to operations for assembling and/or fabricating the discussed structures.

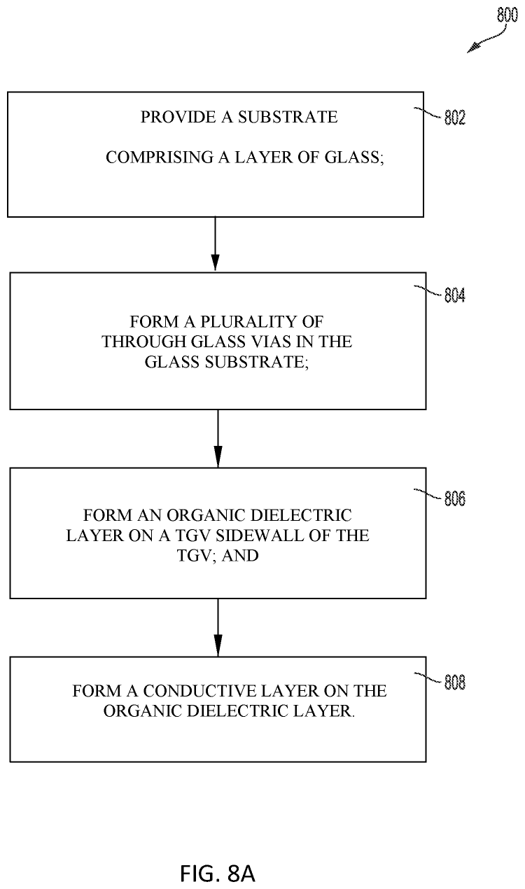

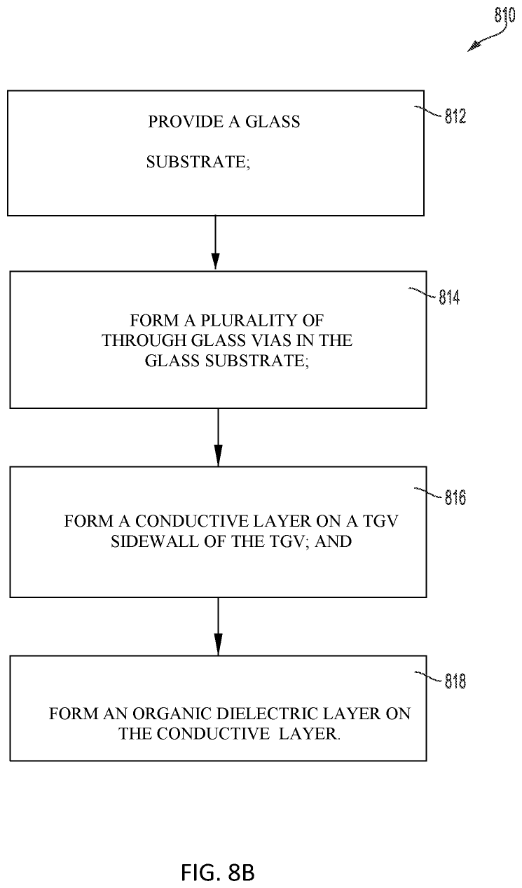

FIG. 8A is a flow chart of a process 800 of fabricating package structures according to some embodiments. For example, process 800 may be used to fabricate any of the microelectronic IC package structures of FIGS. 2A-2K.

As set forth in block 802, a substrate may be provided, wherein the substrate comprises a layer of glass. In an embodiment, the layer of glass may comprise aluminosilicate, borosilicate, alumino-borosilicate, silica, and fused silica. The layer of glass may include one or more additives, such as Al2O3, B2O3, MgO, CaO, SrO, BaO, SnO2, Na2O, K2O, SrO, P2O3, ZrO2, Li2O, Ti, and Zn. The layer of glass may comprise silicon and oxygen, as well as any one or more of aluminum, boron, magnesium, calcium, barium, tin, sodium, potassium, strontium, phosphorus, zirconium, lithium, titanium, and zinc. The layer of glass may comprise at least 23 percent Silicon and at least 26 percent Oxygen by weight, and further comprising at least 5 percent Aluminum by weight. The layer of glass may be a solid bulk material layer that may have been previously formed into any shape in plan view (e.g., x-y plane) suitable for a packaging workpiece, such as rectangular. In an embodiment, the layer of glass has a thickness that may vary with implementation, for example to limit warpage while remaining thin enough to permit the formation of through vias at a pitch as small as is enabled by the surface flatness of the layer of glass. In an embodiment, a thickness of the layer of glass is advantageously 200 microns to 2000 microns.

The layer of glass is advantageously predominantly silicon and oxygen. In some embodiments, the layer of glass comprises at least 23 percent silicon and at least 26 percent oxygen, by weight (i.e., wt. %). In some embodiments where the layer of glass comprises at least 23 wt. % Si and at least 26 wt. % O, the layer of glass further comprises at least 5 wt. % Al. Additives within glass may form suboxides (A2O) monoxides (AO), binary oxides (AO2), ternary oxides (ABO3), and mixtures thereof. For example, glass may comprise AlOx (e.g., Al2O3), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx (e.g., P2O3), ZrOx (e.g., ZrO2), LiOx (e.g., Li2O), TiOx (e.g., TiO2), or ZnOx (e.g., ZnO2). Depending on chemical composition, glass may therefore be referred to as silica, fused silica, aluminosilicate, borosilicate, or alumino-borosilicate, for example.

At step 804, a plurality of through glass vias (TGVs) are formed in the glass substrate. Conductive filled TGVs, provides vertical electrical connections and facilitate heat dissipation. The plurality of TGVs may be formed utilizing drilling or chemical etching processes. In an embodiment, any process known to be suitable for forming TGVs in bulk glass may be utilized. In some embodiments, a laser ablation process, a glass etch process (laser-assisted, or otherwise), or any other such techniques known to be suitable for forming features (e.g., holes) through a thickness of the glass may be employed to achieve a desired diameter and feature pitch. A laser induced direct etching (LIDE) technique may be used to sensitize etch the glass initially. The glass substrate is then preferentially etched at laser sensitized zone using hydrofluoric acid to form the TGV opening structure.

At step 806, an organic dielectric layer may be formed on a sidewall of the TGV. In an embodiment, the organic dielectric layer may be formed on the TGV sidewalls by using such processes as slit coating, lamination or molding methods. Molding processes may include but are not limited to compression molding, lamination, hot pressing or transfer molding. The organic dielectric layer may comprise such organic materials as epoxy mold compounds, build-up dielectric (ABF), photo-imageable dielectric (PID) such as polyimide. The organic dielectric material may have micro or nano sized particulate fillers, or a mixture of fibers and particulate fillers. The fillers in the material may include silicates, quartz, mica, silicate, titanium dioxide, amorphous silicas, magnesium carbonate, aluminum nitride, alumina, boron nitride, magnesium hydroxide, chalk, limestone, feldspar, barium sulfate, solid or hollow fillers, permanently magnetic metal compounds, and/or alloys or mixtures thereof. A thickness of the organic dielectric layer may comprise below about 25% of a diameter of the TGV opening, in an embodiment.

After the molding process, the organic dielectric material (which may comprise a polymeric organic dielectric material) may be plugged into the plurality of TGVs. The organic dielectric material may then be drilled by mechanical drilling, laser drilling, ultra violet (UV) lithography to form vias lined with the organic dielectric material. In an embodiment, the organic dielectric layer on the sidewall of the glass substrate may comprise a polymer vias within a glass vias (via in via) that enhances the mechanical strength of the glass and prevents stress crack formation and propagation.

In an embodiment, the organic dielectric layer may comprise a plurality of hollow filler structures. In an embodiment, the hollow filler structures may comprise roughly spherical hollow structures, and may comprise a weight percentage within the organic dielectric layer of about 1-85%.

At step 808, a conductive layer may be formed on the organic dielectric layer. In an embodiment, the conductive layer may comprise copper or copper alloy materials. In an embodiment, a copper seed layer may be initially deposited (using any suitable deposition processes) on the organic dielectric layer, and then copper may be plated on the seed layer, such that the TGVs are filled with conductive layer. Subsequent to filling the TGVs with the conductive layer, top or bottom surfaces of the substrate may be grinded or polished to form a flat surface. In an embodiment, a layer of the conductive material may be formed on a surface of the substrate to conductively couple each of the TGVs with each other, as shown in FIG. 1B, for example.

In an alternative embodiment, subsequent to conductive seed layer deposition, a thin layer of the conductive layer is plated on the surface of TGVs forming a conductive path, or the TGVs may be plated and then drilled leaving a center portion of the TGVs open. An additional amount of the organic dielectric material may then be placed (using molding processing or any other suitable process) within the TGVs in order to fill a center portion of the TGVs with the additional organic dielectric material. Consequently, a glass-organic dielectric layer-conductive layer-organic dielectric layer structure may be formed to improve the reliability of the substrate.

FIG. 8B is a flow chart of a process 810 of fabricating package structures according to some embodiments. For example, process 810 may be used to fabricate any of the microelectronic IC package structures of FIGS. 4A-4C.

As set forth in block 812, a substrate may be provided, wherein the substrate comprises a layer of glass. In an embodiment, the layer of glass may comprise aluminosilicate, borosilicate, alumino-borosilicate, silica, and fused silica. The layer of glass may include one or more additives, such as Al2O3, B2O3, MgO, CaO, SrO, BaO, SnO2, Na2O, K2O, SrO, P2O3, ZrO2, Li2O, Ti, and Zn. The layer of glass may comprise silicon and oxygen, as well as any one or more of aluminum, boron, magnesium, calcium, barium, tin, sodium, potassium, strontium, phosphorus, zirconium, lithium, titanium, and zinc. The layer of glass may comprise at least 23 percent silicon and at least 26 percent oxygen by weight, and further comprising at least 5 percent aluminum by weight. In exemplary embodiments, a thickness of the layer of glass is advantageously 200 microns to 2000 microns.

At step 814, a plurality of through glass vias (TGVs) are formed in the glass substrate. The plurality of (TGVs) may be formed utilizing drilling or chemical etching processes. In an embodiment, any process known to be suitable for forming TGVs in bulk glass may be utilized. In some embodiments, a laser ablation process, a glass etch process (laser-assisted, or otherwise), or any other such techniques known to be suitable for forming features (e.g., holes) through a thickness of the glass may be employed to achieve a desired diameter and feature pitch.

At step 816, a conductive layer may be formed on the organic dielectric layer. In an embodiment, the conductive layer may comprise copper or copper alloy materials. In an embodiment, a copper seed layer may be initially deposited (using any suitable deposition processes) on the organic dielectric layer, and then the conductive layer may be plated on the seed layer. The conductive layer is only plated on the surface of TGVs to form a conductive path. The center of the TGVs remain open.

In another embodiment, a material, such as Parylene (C|C16H14C12) or a thin metal liner which is different in composition from the conductive layer, is deposited directly on the TGV glass sidewalls prior to the formation of the conductive layer, wherein the Parylene or thin metal layer acts as a stress buffer layer. The conductive layer is then plated onto the Parylene or a thin metal liner side wall leaving the center of the TGVs open.

At step 818, a molding process is then performed to fill the center of the TGVs with an organic dielectric material (such as those organic dielectric materials employed in FIG. 8A). In an embodiment, the conductive material is in direct contact with the glass substrate, however the organic dielectric plug in the center exhibits good adhesion to the conductive layer and its low modulus can reduce the thermal contraction of the conductive layer, as well balances the thermal stress and prevents the conductive layer from delaminating from the glass substrate. Subsequent to filling the TGVs with the conductive layer, top or bottom surfaces of the substrate may be grinded or polished to form a flat surface. In an embodiment, the organic dielectric layer may comprise a plurality of hollow filler structures. In an embodiment, the hollow filler structures may comprise roughly spherical hollow structures and may comprise a weight percentage within the organic dielectric layer of about 1-85%.

The embodiments described herein enable the fabrication of improved TGV structures for 2.5 to 3D devices The structures and methods disclosed increase the reliability of package structures incorporating TGVs with organic dielectric based liner materials. The cost-efficient process described herein prevent TGV failure. Molding equipment used in this disclosure facilitate the plugging of dielectrics into TGV structures. A wide range of organic dielectric materials can be selected with suitable CTE and modulus to buffer the stress of conductive plated TGVs during thermal cycling.

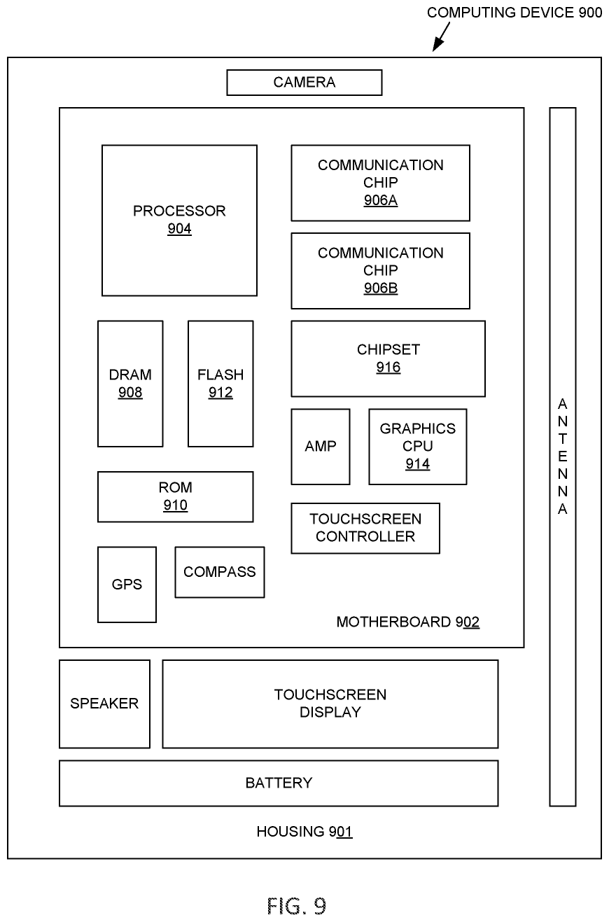

FIG. 9 illustrates an electronic or computing device 900 in accordance with one or more implementations of the present description. The computing device 900 may include a housing 901 having a board 902 disposed therein. The computing device 900 may include a number of integrated circuit components, including but not limited to a processor 904, at least one communication chip 906A, 906B, volatile memory 908 (e.g., DRAM), non-volatile memory 910 (e.g., ROM), flash memory 912, a graphics processor or CPU 914, a digital signal processor (not shown), a crypto processor (not shown), a chipset 916, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 902. In some implementations, at least one of the integrated circuit components may be a part of the processor 904.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include an apparatus having a substrate comprising a layer of glass, the substrate comprising one or more through glass vias (TGVs) extending through the layer of glass, the one or more TGVs comprising a TGV sidewall, an organic dielectric layer on the sidewall; and a conductive layer on the organic dielectric layer.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-9. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, where a first example is an apparatus, comprising a substrate, the substrate comprising a layer of glass. The substrate comprises one or more through glass vias (TGVs) extending through the layer of glass, wherein individual ones of the one or more TGVs comprise a TGV sidewall, the TGV sidewall comprising a TGV length equal to a thickness of the substrate. An organic dielectric layer is on the TGV sidewall, and a conductive layer is on the organic dielectric layer.

In second examples, wherein the first example further comprises wherein the conductive layer comprises at least one of copper or a copper alloy.

In third examples, for any of examples 1-2, further comprising wherein the organic dielectric layer comprises one or more of an epoxy mold compound, a build up dielectric, or a photo-imageable dielectric (PID).

In fourth examples, for any of examples 1-3, wherein the organic dielectric layer comprises a filler material therein, the filler material comprising one or more of silicate, quartz, mica, titanium dioxide, amorphous silica, magnesium carbonate, aluminum nitride, alumina, boron nitride, magnesium hydroxide, chalk, limestone, feldspar, or barium sulfate.

In fifth examples, wherein the fourth example further includes wherein the filler material comprises a hollow filler material.

In sixth examples, wherein the fifth example further includes wherein a concentration of the hollow filler material within the organic dielectric layer comprises 1 to 85 percent by weight.

In seventh examples, for any of examples 1-6, wherein the organic dielectric layer comprises a first organic dielectric layer, and wherein a second organic dielectric layer is on the conductive layer opposite the first organic dielectric layer.

In eighth examples, for any of examples 1-7, wherein the individual ones of the one or more TGVs are filled with the conductive layer.

In the ninth examples, for any of examples 1-8 wherein the conductive layer comprises a lateral width that is greater than twice a lateral width of the organic dielectric layer.

In the tenth examples, for any of examples 1-9 wherein a surface conductive layer is on a surface of the substrate and is in contact with the one or more TGVs.

In the eleventh examples, for any of examples 1-10 wherein the substrate comprises a glass interposer or a glass core structure, the glass interposer or the glass core structure being rectangular in shape in plan view.

In the twelfth examples, for any of examples 1-11 further comprising a die coupled to the substrate.

A thirteenth example is an apparatus, comprising: a substrate comprising a layer of glass, the substrate comprising one or more through glass vias (TGVs) extending through the layer of glass, wherein individual ones of the one or more TGVs comprise: a TGV sidewall, the TGV sidewall comprising a TGV length equal to a thickness of the substrate; a conductive layer adjacent the TGV sidewall; and an organic dielectric layer on the conductive layer.

In the fourteenth examples, the thirteenth example further comprising wherein a parylene layer is between the conductive layer and the TGV sidewall.

In the fifteenth examples, for any of examples 13-14 wherein the organic dielectric layer comprises a thickness that is greater than twice a thickness of the conductive layer, and wherein the organic dielectric layer fills the individual ones of the one or more TGVs.

In the sixteenth examples, for any of examples 13-15 wherein the organic dielectric layer comprises a filler material therein, the filler material comprising one or more of silicate, quartz, mica, titanium dioxide, amorphous silica, magnesium carbonate, aluminum nitride, alumina, boron nitride, magnesium hydroxide, chalk, limestone, feldspar, or barium sulfate.

In seventeenth examples, for any of examples 13-16 further comprising a die coupled to the substrate.

The eighteenth example is a method comprising providing a substrate comprising a layer of glass; forming a one or more of through glass vias (TGVs) in the substrate; forming an organic dielectric layer on a TGV sidewall of individual ones of the one or more TGVs; and forming a conductive layer on the organic dielectric layer.

In the nineteenth examples, the eighteenth example further comprising forming an additional organic dielectric layer on the conductive layer.

In the twentieth examples, for any of examples 18-19, further comprising forming a parylene layer between the organic dielectric layer and the conductive layer, wherein the organic dielectric layer comprises a plurality of hollow filler materials therein.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a substrate comprising a layer of glass, the substrate comprising one or more through glass vias (TGVs) extending through the layer of glass, wherein individual ones of the one or more TGVs comprise:
a TGV sidewall, the TGV sidewall comprising a TGV length equal to a thickness of the substrate;
an organic dielectric layer on the TGV sidewall; and
a conductive layer on the organic dielectric layer.

2. The apparatus of claim 1, wherein the conductive layer comprises at least one of copper or a copper alloy.

3. The apparatus of claim 1, wherein the organic dielectric layer comprises one or more of an epoxy mold compound, a build up dielectric, or a photo-imageable dielectric (PID).

4. The apparatus of claim 1, wherein the organic dielectric layer comprises a filler material therein, the filler material comprising one or more of silicate, quartz, mica, titanium dioxide, amorphous silica, magnesium carbonate, aluminum nitride, alumina, boron nitride, magnesium hydroxide, chalk, limestone, feldspar, or barium sulfate.

5. The apparatus of claim 4, wherein the filler material comprises a hollow filler material.

6. The apparatus of claim 5, wherein a concentration of the hollow filler material within the organic dielectric layer comprises 1 to 85 percent by weight.

7. The apparatus of claim 1, wherein the organic dielectric layer comprises a first organic dielectric layer, and wherein a second organic dielectric layer is on the conductive layer opposite the first organic dielectric layer.

8. The apparatus of claim 1, wherein the individual ones of the one or more TGVs are filled with the conductive layer.

9. The apparatus of claim, 1 wherein the conductive layer comprises a lateral width that is greater than twice a lateral width of the organic dielectric layer.

10. The apparatus of claim 1, wherein a surface conductive layer is on a surface of the substrate and is in contact with the one or more TGVs.

11. The apparatus of claim 1, wherein the substrate comprises a glass interposer or a glass core structure, the glass interposer or the glass core structure being rectangular in shape in plan view.

12. The apparatus of claim 1, further comprising a die coupled to the substrate.

13. An apparatus, comprising:
a substrate comprising a layer of glass, the substrate comprising one or more through glass vias (TGVs) extending through the layer of glass, wherein individual ones of the one or more TGVs comprise:
a TGV sidewall, the TGV sidewall comprising a TGV length equal to a thickness of the substrate;
a conductive layer adjacent the TGV sidewall; and
an organic dielectric layer on the conductive layer.

14. The apparatus of claim 13, wherein a parylene layer is between the conductive layer and the TGV sidewall.

15. The apparatus of claim 13, wherein the organic dielectric layer comprises a thickness that is greater than twice a thickness of the conductive layer, and wherein the organic dielectric layer fills the individual ones of the one or more TGVs.

16. The apparatus of claim 13, wherein the organic dielectric layer comprises a filler material therein, the filler material comprising one or more of silicate, quartz, mica, titanium dioxide, amorphous silica, magnesium carbonate, aluminum nitride, alumina, boron nitride, magnesium hydroxide, chalk, limestone, feldspar, or barium sulfate.

17. The apparatus of claim 13, further comprising a die coupled to the substrate.

18. A method, comprising:
providing a substrate comprising a layer of glass;
forming a one or more of through glass vias (TGVs) in the substrate;
forming an organic dielectric layer on a TGV sidewall of individual ones of the one or more TGVs; and
forming a conductive layer on the organic dielectric layer.

19. The method of claim 18, further comprising forming an additional organic dielectric layer on the conductive layer.

20. The method of claim 18, further comprising forming a parylene layer between the organic dielectric layer and the conductive layer, wherein the organic dielectric layer comprises a plurality of hollow filler materials therein.
